(19) United States
(12) Patent Application Publication
(10) Pub. No.: US 2025/0294757 A1
(43) Pub. Date: Sep. 18, 2025

(54) SEMICONDUCTOR STORAGE DEVICE

(71) Applicant: Kioxia Corporation, Tokyo (JP)

(72) Inventor: Hiroshi NAKAKI, Yokkaichi Mie (JP)

(21) Appl. No.: 19/066,069

(22) Filed: Feb. 27, 2025

(30) Foreign Application Priority Data
Mar. 18, 2024 (JP) 2024-042009

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A semiconductor storage device includes conductive layers arranged in a first direction, pillars extending along the first direction and arranged in (2n+1) columns (n is an integer of 1 or more) along a second direction intersecting the first direction, each of the pillars including a semiconductor layer, a plurality of first plugs, each of which is on an upper end portion of a corresponding one of the pillars and electrically connected to the semiconductor layer, and a plurality of bit lines extending along the second direction above the pillars, each of the bit lines being electrically connected to two or more first plugs. Each of the first plugs has an elongated shape at a cross-section taken thereof in a plane perpendicular to the first direction and a longitudinal direction of the cross-section forms an angle with respect to the second direction when viewed from the first direction.

### CROSS-REFERENCE TO RELATED APPLICATION(S)

This application is based upon and claims the benefit of priority from Japanese Patent Application No. 2024-042009, filed Mar. 18, 2024, the entire contents of which are incorporated herein by reference.

### FIELD

Embodiments described herein relate generally to a semiconductor storage device.

### BACKGROUND

High integration is progressing in semiconductor storage devices such as with three-dimensional nonvolatile memories. As a result, pillars in which memory cells are formed are arranged more densely, and it is important to reliably connect bit lines corresponding to each pillar.

### BRIEF DESCRIPTION OF THE DRAWINGS

FIG. 1 is a block diagram illustrating a semiconductor storage device according to an embodiment.

FIG. 2 is an equivalent circuit diagram illustrating a configuration of a memory cell array in the semiconductor storage device.

FIGS. 3A and 3B are diagrams illustrating an example of a schematic configuration of the semiconductor storage device.

FIGS. 4A to 4D are schematic diagrams illustrating an example of a layout of various components in a memory area of the semiconductor storage device.

FIG. 5 is a flowchart illustrating an example of a method of manufacturing the semiconductor storage device.

FIGS. 6A and 6B are schematic diagrams illustrating an example of a layout of various components in a memory area of a semiconductor storage device according to a comparative example.

FIGS. 7A to 7C are schematic diagrams illustrating an example of a layout of various components in a memory area of a semiconductor storage device according to a modification example.

### DETAILED DESCRIPTION

Embodiments provide a semiconductor storage device that can more reliably connect densely arranged pillars to bit lines.

In general, according to one embodiment, a semiconductor storage device comprises: a plurality of conductive layers arranged in a first direction and separated from each other; a plurality of pillars extending along the first direction and arranged in (2n+1) columns (n is an integer of 1 or more) along a second direction intersecting the first direction, each of the pillars including a semiconductor layer; a plurality of first plugs, each of which is on an upper end portion of a corresponding one of the pillars and electrically connected to the semiconductor layer; and a plurality of bit lines extending along the second direction above the pillars, each of the bit lines being electrically connected to two or more of the first plugs. Each of the first plugs has an elongated shape at a cross-section taken thereof in a plane perpendicular to the first direction and a longitudinal direction of the cross-section forms an angle with respect to the second direction when viewed from the first direction.

Hereinafter, embodiments of the present disclosure will be described in detail with reference to the drawings. It should be noted that the present disclosure is not limited to the following embodiments. Components in the following embodiments include those that a person skilled in the art can easily imagine or that are substantially the same.

### (Configuration Example of Semiconductor Storage Device)

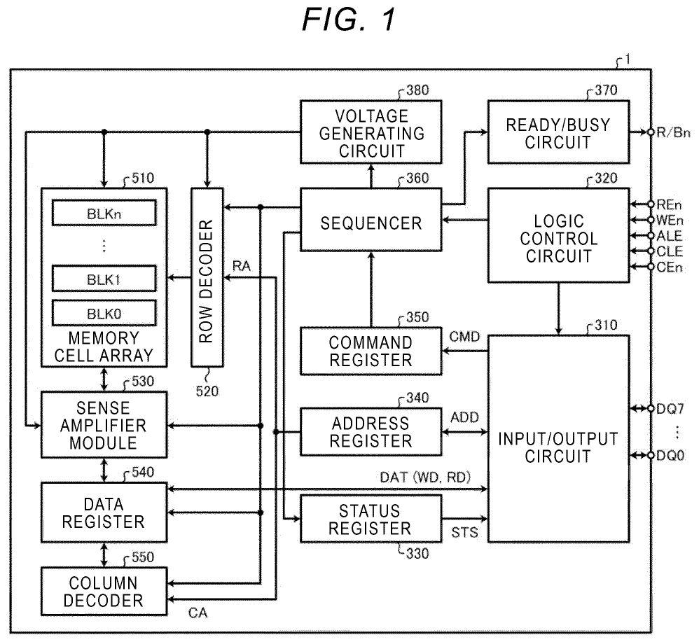

FIG. 1 is a block diagram illustrating a semiconductor storage device 1 according to an embodiment. As illustrated in FIG. 1, the semiconductor storage device 1 includes an input/output circuit 310, a logic control circuit 320, a status register 330, an address register 340, a command register 350, a sequencer 360, a ready/busy circuit 370, a voltage generating circuit 380, a memory cell array 510, a row decoder 520, a sense amplifier module 530, a data register 540, and a column decoder 550.

The input/output circuit 310 controls input/output of a signal DQ to and from an external device such as a memory controller (not illustrated) that controls the semiconductor storage device 1. The input/output circuit 310 includes an input circuit and an output circuit (not illustrated).

The input circuit transmits data DAT such as write data WD received from the external device to the data register 540, transmits an address ADD received from the external device to the address register 340, and transmits a command CMD received from the external device to the command register 350.

The output circuit transmits status information STS received from the status register 330, data DAT such as read data RD received from the data register 540, and the address ADD received from the address register 340 to the external device.

The logic control circuit 320 receives, for example, a chip enable signal CEn, a command latch enable signal CLE, an address latch enable signal ALE, a write enable signal WEn, and a read enable signal REn from the external device. The logic control circuit 320 controls the input/output circuit 310 and the sequencer 360 according to the received signals.

The status register 330 temporarily stores the status information STS and notifies the external device of whether the operation is normally completed, for example, in a write operation, a read operation, and an erase operation of data.

The address register 340 temporarily stores the address ADD received from the external device via the input/output circuit 310. The address register 340 transmits a row address RA to the row decoder 520 and transmits a column address CA to the column decoder 550.

The command register 350 temporarily stores the command CMD received from the external device via the input/output circuit 310 and transmits the command CMD to the sequencer 360.

The sequencer 360 controls the entire operation of the semiconductor storage device 1. More specifically, the sequencer 360 controls, for example, the status register 330, the ready/busy circuit 370, the voltage generating circuit 380, the row decoder 520, the sense amplifier module 530, the data register 540, the column decoder 550, and the like according to the command CMD stored in the command register 350, and executes the write operation, the read operation, the erase operation, and the like.

The ready/busy circuit 370 transmits a ready/busy signal R/Bn to the external device according to an operation status of the sequencer 360.

The voltage generating circuit 380 generates a voltage necessary for the write operation, the read operation, and the erase operation according to control of the sequencer 360 and supplies the generated voltage, for example, to the memory cell array 510, the row decoder 520, the sense amplifier module 530, and the like. The row decoder 520 and the sense amplifier module 530 applies the voltage supplied from the voltage generating circuit 380 to memory cells in the memory cell array 510.

The memory cell array 510 includes a plurality of blocks BLK (BLK0 to BLKn) where n is an integer of 2 or more. The block BLK is a set of a plurality of memory cells associated with bit lines and word lines and is, for example, a unit of data erasure. The memory cell is a transistor and stores nonvolatile data.

The semiconductor storage device 1 is, for example, a NAND-type nonvolatile memory including such memory cells.

The row decoder 520 decodes the row address RA. The row decoder 520 selects any block BLK based on the decoded result. The row decoder 520 applies a necessary voltage to the block BLK.

The sense amplifier module 530 senses data read from the memory cell array 510 in the read operation. Then, the sense amplifier module 530 transmits the read data RD to the data register 540. The sense amplifier module 530 transmits the write data WD to the memory cell array 510 in the write operation.

The data register 540 includes a plurality of latch circuits. The latch circuit stores the write data WD and read data RD. For example, the data register 540 temporarily stores the write data WD received from the input/output circuit 310 and transmits the write data WD to the sense amplifier module 530 in the write operation. For example, the data register 540 temporarily stores the read data RD received from the sense amplifier module 530 and transmits the read data RD to the input/output circuit 310 in the read operation.

The column decoder 550 decodes the column address CA and selects the latch circuit in the data register 540 according to the decoded result, for example, in the write operation, the read operation, and the erase operation.

It should be noted that a circuit group disposed near the memory cell array 510 may be also referred to as a peripheral circuit. The peripheral circuit includes at least the row decoder 520, the sense amplifier module 530, the data register 540, and the column decoder 550. The peripheral circuit may include the status register 330, the address register 340, the command register 350, and the sequencer 360 and may further include the input/output circuit 310, the logic control circuit 320, the ready/busy circuit 370, and the voltage generating circuit 380.

As such, the semiconductor storage device 1 includes the memory cell array 510 including a plurality of memory cells and a peripheral circuit that operates the plurality of memory cells.

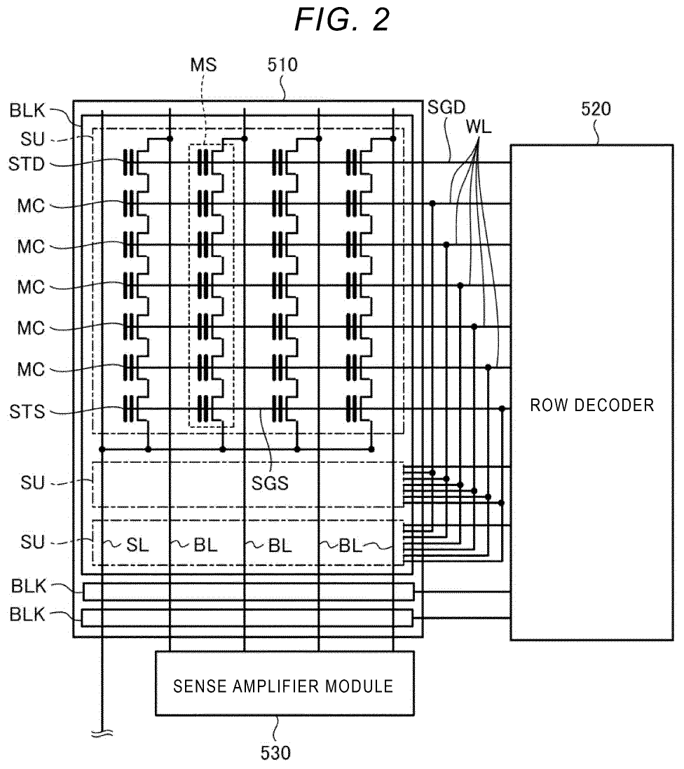

FIG. 2 is an equivalent circuit diagram illustrating an example of a configuration of the memory cell array 510 in the semiconductor storage device 1.

The memory cell array 510 includes the plurality of blocks BLK as described above. The plurality of blocks BLK respectively include a plurality of string units SU. The plurality of string units SU respectively include the plurality of memory strings MS. One end of each of the plurality of memory strings MS is connected to the peripheral circuit such as the sense amplifier module 530 via a corresponding bit line BL. The other end of each of the plurality of memory strings MS is connected to the peripheral circuit via a common source line SL.

The memory string MS includes a drain select transistor STD connected between the bit line BL and the source line SL in series, a plurality of memory cells MC, and a source select transistor STS. Hereinafter, the drain select transistor STD and the source select transistor STS may be simply referred to as a select transistor (STD, STS).

The memory cells MC is, for example, a field effect transistor (FET) including a charge storage layer in a gate insulation layer. A threshold voltage of the memory cell MC changes according to an amount of charge in the charge storage layer. By providing one threshold voltage or a plurality of threshold voltages, the memory cell MC may be able to store one bit or a plurality of bits of data. Word lines WL are respectively connected to gate electrodes of the plurality of memory cells MC corresponding to one memory string MS. The word lines WL are commonly connected to all memory strings MS in one block BLK.

The select transistor (STD, STS) is, for example, a field effect transistor. A select gate line (SGD, SGS) is connected to a gate electrode of the select transistor (STD, STS). A drain select gate line SGD connected to the drain select transistor STD is provided corresponding to the string unit SU and is commonly connected to all memory string MS in one string unit SU. A source select gate line SGS connected to the source select transistor STS is commonly connected to all memory strings MS in one block BLK.

One end of each of the word lines WL and the select gate lines (SGD, SGS) is connected to the peripheral circuit such as the row decoder 520.

### (Physical Configuration Example of Semiconductor Storage Device)

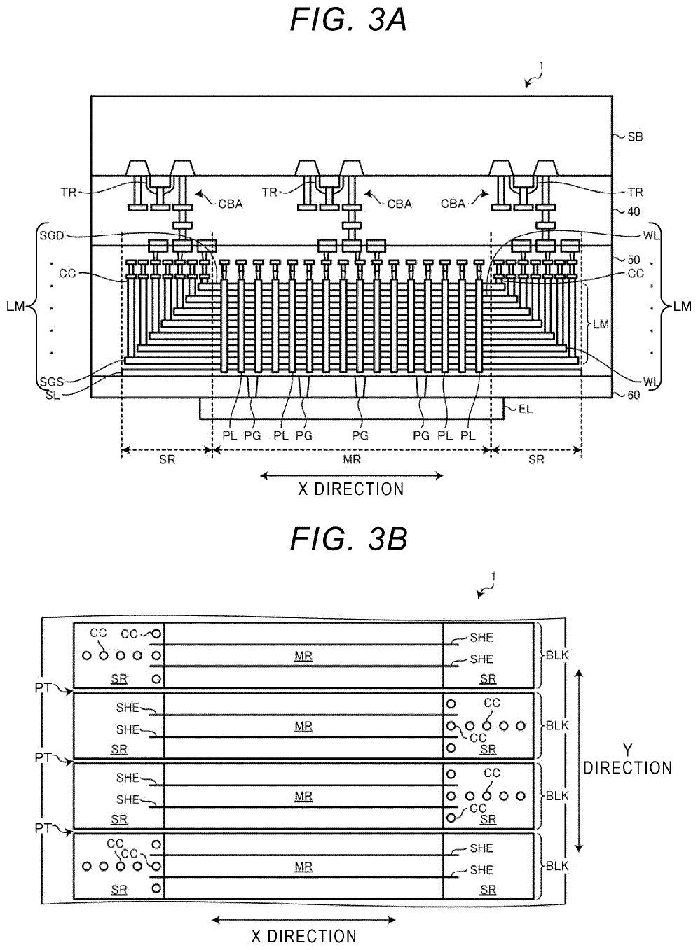

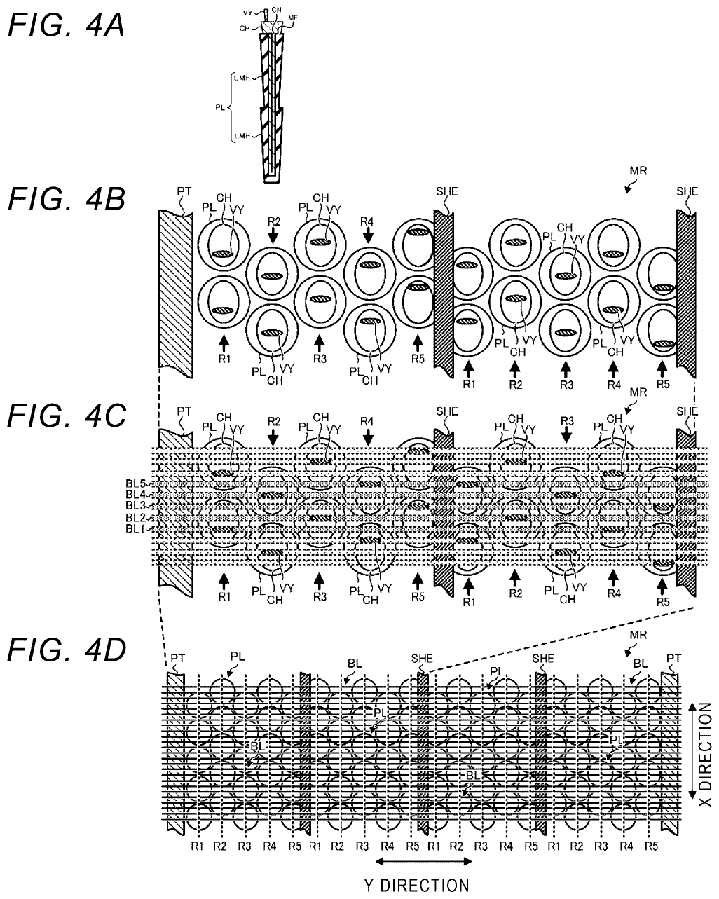

Next, referring to FIGS. 3A and 3B and FIGS. 4A to 4D, a physical configuration of the semiconductor storage device 1 is described.

FIGS. 3A and 3B are diagrams illustrating an example of a schematic configuration of the semiconductor storage device 1. More specifically, FIG. 3A is a cross-sectional view of the semiconductor storage device 1 taken along an X direction, and FIG. 3B is a schematic plan view illustrating a layout of the semiconductor storage device 1.

It should be noted that, in FIG. 3A, hatching is omitted for the ease of viewing the drawing. Also, in FIG. 3A, components that do not necessarily exist on the same cross section are illustrated together, and a part of upper layer wiring and the like are omitted.

In the present specification, both the X direction and a Y direction are directions along a direction of a plane of the word line WL, and the X direction and the Y direction are orthogonal to each other. A direction electrically drawing the word line WL may be referred to as a third direction, and the third direction is the X direction. A direction intersecting the third direction may be referred to as a second direction, and the second direction is the Y direction. It should be noted that the semiconductor storage device 1 may include manufacturing errors, and thus the second direction and the third direction are not necessarily perpendicular to each other. A direction in which the plurality of word lines WL are stacked may be referred to as a first direction, and the first direction is a vertical direction of the semiconductor storage device 1.

As illustrated FIG. 3A, the semiconductor storage device 1 includes an electrode film EL, the source line SL, a stacked body LM, and a semiconductor substrate SB provided with a peripheral circuit CBA in an order from the lower side of the page. One or more select gate lines SGS, the plurality of word lines WL, and one or more select gate lines SGD are stacked in the stacked body LM while being separated from each other.

The source line SL is disposed on the electrode film EL with an insulating layer 60 interposed therebetween. A plurality of plugs PG are arranged in the insulating layer 60, and the source line SL and the electrode film EL are electrically connected via the plugs PG. Though not illustrated, an electrode pad for supplying electric power and signal from outside to the semiconductor storage device 1 is provided in the same layer as the electrode film EL. The select gate line SGS, the plurality of word lines WL, and the select gate line SGD are stacked in the source line SL in this order and configures the stacked body LM.

With the above configuration, a source voltage can be applied to the source line SL from the voltage generating circuit 380 (see FIG. 1) via the electrode film EL and the plug PG.

As illustrated in FIGS. 3A and 3B, a memory area MR is disposed in a central portion of the stacked body LM in the X direction, and staircase areas SR are respectively arranged on both end portions of the stacked body LM in the X direction. The memory area MR and the staircase areas SR are divided into a plurality of areas by a plurality of plate-like portions PT penetrating the plurality of word lines WL and the like and extending in the X direction.

It should be noted that an area disposed between the plate-like portions PT adjacent to each other in the Y direction and including the memory area MR and the staircase areas SR is an example of a physical configuration corresponding to one block BLK described above (see FIG. 2). As described above, the memory area MR is provided with the plurality of memory cells MC (see FIG. 2) that store data in a nonvolatile manner, and the block BLK becomes a unit of data erasure.

A plurality of separation layers SHE penetrating the select gate line SGD and extending in the X direction are arranged between the plate-like portions PT adjacent to each other in the Y direction. The plurality of separation layers SHE extend in the X direction across the entire memory area MR and reach a part of the staircase areas SR at both end portions in the X direction. The plurality of separation layers SHE are insulating layers such as silicon oxide layers.

As described above, the area partitioned into a pattern of the select gate line SGD by the separation layers SHE between the plate-like portions PT adjacent to each other is an example of a physical configuration corresponding to the string unit SU (see FIG. 2).

A plurality of pillars PL penetrating the word lines WL and the select gate lines SGD and SGS in the stacking direction are arranged in the memory area MR. The lower end of the pillar PL reaches the source line SL. The plurality of memory cells MC are formed at intersections of the pillars PL and the word lines WL. Accordingly, the semiconductor storage device 1 functions as, for example, a three-dimensional nonvolatile memory in which memory cells MC are three-dimensionally arranged in the memory area MR.

As such, the memory area MR is an example of a physical configuration corresponding to the memory cell array 510 (see FIG. 2). The pillar PL is an example of a physical configuration corresponding to the memory string MS (see FIG. 2) in which the memory cells MC and the like are connected in series.

In the staircase area SR, the plurality of word lines WL and the select gate lines SGD and SGS are processed and terminated in a staircase shape. Here, as a distance from the memory area MR increases in the X direction, the plurality of word lines WL and the select gate lines SGD and SGS configuring a terrace portion move from an upper layer side to a lower layer side, and thus a height position of the terrace portion decreases toward the source line SL side.

It should be noted that the separation layers SHE extend from the memory area MR to a portion where the select gate lines SGD of the staircase areas SR are processed in a staircase shape. As a result, the select gate line SGD is separated into a plurality of areas within one block BLK. In other words, the separation layer SHE penetrates an upper layer portion above the plurality of word lines WL so that the upper layer portion of the stacked body LM is partitioned into a pattern of the plurality of select gate lines SGD.

Contacts CC connected to the word lines WL and the select gate lines SGD and SGS of each layer are respectively arranged in the terrace portions of each step configured with the plurality of word lines WL and the select gate lines SGD and SGS. In the word lines WL and the select gate line SGS, one contact CC is connected to one layer. In the select gate line SGD, one contact CC is connected to each section separated by the separation layer SHE in one layer.

Here, in one block BLK, the plurality of contacts CC are arranged on one of the staircase regions SR on both sides in the X direction. When viewed from one side in the X direction, the plurality of contacts CC are arranged, for example, for every two blocks BLK.

That is, in the example of FIG. 3B, in the uppermost block BLK of the page, the plurality of contacts CC are arranged, for example, in the left staircase area SR of the page of the staircase area SR on both end portions in the X direction. In the blocks BLK located one block below and two blocks below of the above-described block BLK, the plurality of contacts CC are arranged in the right staircase areas SR of the page of the staircase areas SR on both end portions in the X direction. In the lowermost block BLK of the page, the plurality of contacts CC are arranged in the left staircase area SR of the page again.

As illustrated in FIG. 3A, the contacts CC of the staircase areas SR on both end portions in the X direction each belong to different blocks BLK and are not actually positioned in the same cross section.

By such contacts CC, the word lines WL and the like stacked in multiple layers are individually drawn. More specifically, a write voltage, a read voltage, and the like are applied from the contacts CC to the memory cells MC in the memory areas MR in the central portions of the plurality of word lines WL via the word lines WL at the same height position as the memory cells MC.

It should be noted that, in the present specification, a direction facing terrace surfaces of the word lines WL and the like processed in a staircase shape is defined as an upper side of the semiconductor storage device 1.

The plurality of word lines WL, the select gate lines SGD and SGS, the pillars PL, and the contacts CC are covered with an insulating layer 50. The insulating layer 50 extends around the components.

The semiconductor substrate SB on the insulating layer 50 is, for example, a silicon substrate. The peripheral circuits CBA such as the row decoder 520 and the sense amplifier module 530 (see FIG. 1) including transistors TR, wirings, and the like are arranged on a surface of the semiconductor substrate SB. Various voltages applied from the contacts CC to the memory cells MC are controlled by the peripheral circuits CBA electrically connected to the contacts CC. As a result, the peripheral circuit CBA controls electrical operations of the memory cells MC.

The peripheral circuit CBA is covered with an insulating layer 40, and the insulating layer 40 is bonded to the insulating layer 50 that covers the plurality of word lines WL and the like to configure the semiconductor storage device 1 including components such as the plurality of word lines WL, the select gate lines SGD and SGS, the pillars PL, the contacts CC, and the like, and the peripheral circuits CBA.

FIGS. 4A to 4D are schematic diagrams illustrating an example of a layout of various components in the memory area MR of the semiconductor storage device 1.

More specifically, FIG. 4A is a schematic diagram illustrating a detailed configuration of the pillar PL. FIGS. 4B and 4C are partial enlarged views of the memory area MR, FIG. 4B is a diagram in which the bit lines BL are omitted, and FIG. 4C is a diagram in which the bit lines BL are illustrated. FIG. 4D is a schematic top view illustrating a part of the memory area MR.

As illustrated in FIG. 4D and as described above, the memory area MR between the plate-like portions PT adjacent to each other in the Y direction is separated into a plurality of sections by the plurality of separation layers SHE extending in the X direction.

The plurality of pillars PL are arranged in a plurality of columns extending in the X direction between the plate-like portions PT and the separation layers SHE adjacent to each other in the Y direction and between the separation layers SHE adjacent to each other in the Y direction. In the columns of FIG. 4D, the plurality of pillars PL are arranged in five columns R1 to R5. However, one end side of each of the pillars PL in the Y direction that belong to the column R1 and the column R5 adjacent to the separation layers SHE overlaps with a separation layer SHE when viewed in the stacking direction of the stacked body LM.

In the arrangement of the pillars PL, the pillars PL that belong to the columns R1 and R2 adjacent to each other, the columns R2 and R3 adjacent to each other, the columns R3 and R4 adjacent to each other, and the columns R4 and R5 adjacent to each other are deviated in the Y direction not to be overlapped with each other in the Y direction. Meanwhile, the pillars PL that belong to the columns R1, R3, and R5 separated from each other and the columns R2 and R4 separated from each other are arranged so that the positions thereof in the Y direction match each other. As a result, the plurality of pillars PL are arranged, for example, in a staggered arrangement when viewed in the stacking direction of the stacked body LM. More preferably, the plurality of pillars PL are arranged to have substantially same intervals therebetween.

It should be noted that, as described above, by arranging the plurality of pillars PL to allow interference between a part of pillars PL and the separation layers SHE, periodical arrangement such as the staggered arrangement of the pillars PL can be maintained. As a result, when forming the plurality of pillars PL at a high density, a processing accuracy of the pillars PL can be improved. It should be noted that, as described above, the separation layers SHE are, for example, insulating layers. Even if the separation layers SHE come into contact with the pillars PL, the separation layers SHE do not affect electrical characteristics of the pillars PL.

Above the pillars PL, for example, the plurality of bit lines BL each extending in the Y direction are arranged to be separated from each other at a predetermined distance in the X direction. More preferably, the plurality of bit lines BL are arranged to be separated at substantially equal intervals in the X direction.

Each of the pillars PL is electrically connected to any of the bit lines BL. Here, to enable the memory cells MC that belong to each of the pillars PL to be individually driven, the pillars PL arranged between the plate-like portions PT and the separation layers SHE adjacent to each other in the Y direction and between the separation layers SHE adjacent to each other in the Y direction are respectively connected to different bit lines BL.

Here, the stacked body LM has a two-tier structure in which sacrifice layers corresponding to the plurality of word lines WL are stacked in two stages. In the stacked body LM having the two-tier structure, the staircase shape of the pillars PL and the staircase areas SR is also formed in two stages.

As illustrated in FIG. 4A, a MANOS structure is formed inside the pillar PL, the MANOS structure including a semiconductor layer CN extending in the stacking direction of the stacked body LM and an insulating layer ME having a multilayer structure. According to such MANOS structure, the memory cells MC are formed at intersections of the pillars PL and the word lines WL, and the select transistors STD and STS (see FIG. 2) are formed at intersections of the pillars PL and the select gate lines SGD and SGS.

It should be noted that one end side in the Y direction of each of the pillars PL that belong to the column R1 and are arranged in an area between the plate-like portion PT and the separation layer SHE overlaps with the separation layer SHE at the height of the select gate line SGD, and thus overlapping portions are lost. The select gate line SGD that surrounds the periphery of the pillars PL of the column R1 also overlaps with the separation layer SHE, and thus overlapping portions are lost. However, the select transistor STD formed at intersections of the pillars PL and the select gate line SGD is adjusted to function as the select transistor STD also in the pillars PL of the column R1. The separation layer SHE does not reach the height of the word line WL, and portions of the pillars PL of the column R1 are not lost. Portions of the word lines are also not lost. Therefore, naturally, the memory cells MC formed at intersections of the pillars of the column R1 and the word lines WL function.

Similarly, one end side in the Y direction of each of the pillars PL that belong to the column R5 and arranged in an area between two separation layers SHE overlaps with the separation layer SHE at the height of the select gate line SGD, and thus overlapping portions are lost. The select gate line SGD that surrounds the periphery of the pillars PL of the column R5 also overlaps with the separation layer SHE, and thus overlapping portions are lost. However, the select transistor STD formed at intersections of the pillars PL and the select gate line SGD is adjusted to function as the select transistor STD also in the pillars PL of the column R5. The separation layer SHE does not reach the height of the word line WL, and portions of the pillars PL of the column R5 are not lost. Portions of the word lines are also not lost. Therefore, naturally, the memory cells MC formed at intersections of the pillars of the column R5 and the word lines WL function.

For example, in the stacked body LM having the two-tier structure, the pillar PL includes a lower pillar LMH disposed in a lower layer portion of the stacked body LM and an upper pillar UMH disposed in the upper layer portion of the stacked body LM and connected to the lower pillar LMH. Plugs CH and VY are arranged in an upper end portion of the pillar PL in this order from the pillar PL side, and individual pillars PL are connected to the upper bit lines BL via the plugs CH and VY.

As illustrated in FIG. 4B, the pillars PL have a circular shape when viewed in the stacking direction of the stacked body LM. However, the pillars PL may have another shape such as an oval shape or an elliptic shape.

The plug CH in the upper end portion of the pillar PL has, for example, an elliptic shape when viewed in the stacking direction of the stacked body LM, in which a longitudinal direction thereof is in the X direction. That is, the plug CH has an elongated shape at a cross-section taken thereof in a plane perpendicular to the direction perpendicular to the X and Y directions. A longitudinal direction of the cross-section forms an angle with respect to the Y direction. However, as long as the longitudinal direction of the plug CH is in the X direction, the plug CH may have another shape such as an oval shape or a rectangular shape with rounded corners. A length of the plug CH in the longitudinal direction may be, for example, 1.1 times or more and less than two times of a length of the plug CH in a lateral direction.

An outer shape of the plug CH when viewed in the stacking direction of the stacked body LM is smaller than an outer shape of the pillar PL and is within a range of an upper surface of the pillar PL. A center of the plug CH when viewed in the stacking direction of the stacked body LM substantially coincides with the center of the corresponding pillar PL.

Meanwhile, the plug VY disposed on the upper surface of the plug CH has, for example, an elliptic shape in which a longitudinal direction thereof is in the Y direction. That is, the plug VY extends in the direction in which the bit line BL extends.

A center of the plug VY when viewed in the stacking direction of the stacked body LM substantially coincides with the center of the corresponding pillar PL and the plug CH in the Y direction and is deviated in the X direction. Here, in the pillars PL arranged between the plate-like portion PT and the separation layer SHE adjacent to each other in the Y direction and between the separation layers SHE adjacent to each other in the Y direction, the deviation amount between the center of the plug VY and the center of the corresponding pillar PL and the corresponding plug CH varies depending on each pillar PL so that the pillars PL are respectively connected to different bit lines BL.

As illustrated in FIG. 4C, when the bit lines BL overlap with FIG. 4B, according to the above configuration, it is understood that the pillars PL arranged between the plate-like portion PT and the separation layer SHE adjacent to each other in the Y direction and between the separation layers SHE adjacent to each other in the Y direction are respectively connected to different bit lines BL.

More specifically, the position of each plug VY in the X direction is determined to match the position of the bit line BL to be connected among the plurality of bit lines BL in the X direction. Therefore, as described above, the deviation amounts between the centers of the plugs VY and the centers of the corresponding pillar PL and the corresponding plugs CH in the X direction are individually different. Therefore, by displacement of the centers, the pillars PL arranged between the plate-like portion PT and the separation layer SHE and between the separation layers SHE can be respectively connected to different bit lines BL.

That is, in the example illustrated in FIG. 4C, a pillar PL that is between the plate-like portion PT and the separation layer SHE adjacent to each other in the Y direction and belongs to the column R1 is connected to a bit line BL1 via the plugs CH and VY. A pillar PL that is close to the pillar PL of the column R1 connected to the bit line BL1 and belongs to the column R2 is connected to a bit line BL4 via the plugs CH and VY. A pillar PL that is close to the pillar PL of the column R2 connected to the bit line BL4 and belongs to the column R3 is connected to a bit line BL2 via the plugs CH and VY. A pillar PL that is close to the pillar PL of the column R3 connected to the bit line BL2 and belongs to the column R4 is connected to a bit line BL5 via the plugs CH and VY. A pillar PL that is close to the pillar PL of the column R4 connected to the bit line BL5 and belongs to the column R5 is connected to a bit line BL3 via the plugs CH and VY.

In the example illustrated in FIG. 4C, a pillar PL that is between the separation layers SHE adjacent to each other in the Y direction and belongs to the column R1 is connected to the bit line BL5 via the plugs CH and VY. A pillar PL that is close to the pillar PL of the column R1 connected to the bit line BL5 and belongs to the column R2 is connected to the bit line BL2 via the plugs CH and VY. A pillar PL that is close to the pillar PL of the column R2 connected to the bit line BL2 and belongs to the column R3 is connected to the bit line BL4 via the plugs CH and VY. A pillar PL that is close to the pillar PL of the column R3 connected to the bit line BL4 and belongs to the column R4 is connected to the bit line BL1 via the plugs CH and VY. A pillar PL that is close to the pillar PL of the column R4 connected to the bit line BL1 and belongs to the column R5 is connected to the bit line BL3 via the plugs CH and VY.

As such, the plurality of bit lines BL are connected to any one of the pillars PL of each of the columns R1 to R5 in a cycle of five columns. In other words, in the arrangement of the plurality of pillars PL, the pillars PL that belong to any one of the same column of the columns R1 to R5 are connected to the bit line BL at the interval of five that is the same number as the arrangement number of the pillars PL among the plurality of bit lines BL arranged in the Y direction.

### (Method of Manufacturing Semiconductor Storage Device)

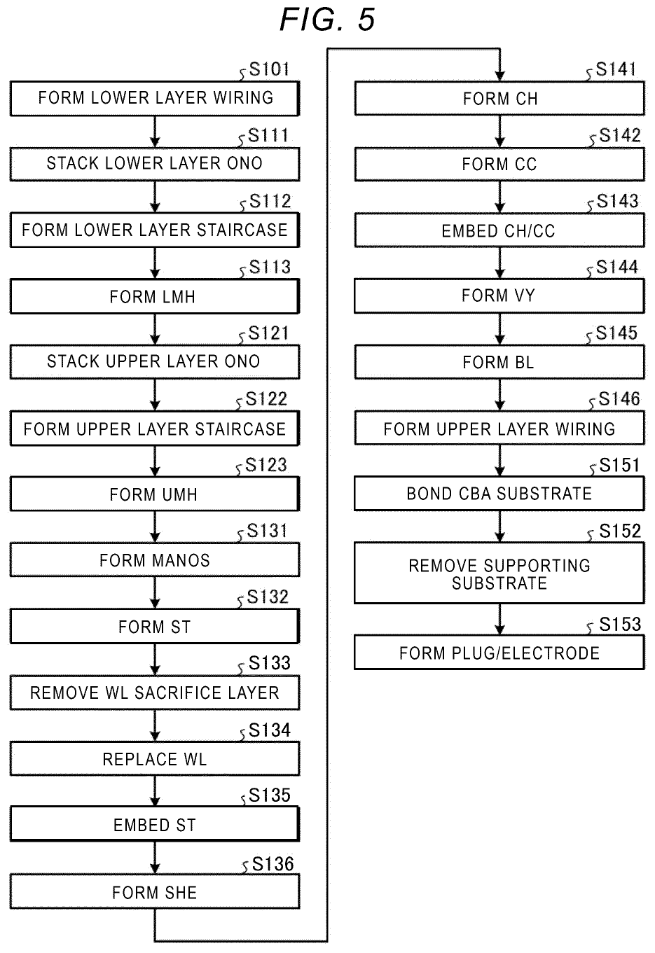

Next, a method of manufacturing the semiconductor storage device 1 is described with reference to FIG. 5. FIG. 5 is a flowchart illustrating an example of the method of manufacturing the semiconductor storage device 1.

As illustrated in FIG. 5, a lower layer wiring or the like such as the source line SL is formed on a supporting substrate such as a silicon substrate (step S101).

Next, a lower layer ONO structure is stacked on the source line SL by stacking sacrifice layers such as a plurality of silicon oxide layers while being separated from each other and a first-stage stacked body is formed (step S111). Alower layer staircase is formed by processing a part of the first-stage stacked body into a staircase shape and the insulating layer 50 covers the lower layer staircase (step S112).

The lower pillar LMH to be the lower structure of the pillar PL is formed in the first-stage stacked body (step S113). It should be noted that, here, the lower pillar LMH is filled with a sacrifice layer such as an amorphous silicon layer.

Next, the plurality of sacrifice layers such as silicon oxide layers are stacked while being separated from each other on the first-stage stacked body to stack an upper layer ONO structure, and a second-stage stacked body is formed (step S121). A part of the second-stage stacked body is processed into a staircase shape to form an upper layer staircase, and the upper layer staircase is embedded in the insulating layer 50 (step S122).

Memory holes for the upper pillars UMH that are the upper structures of the pillars PL are formed in the second-stage stacked body (step S123). The sacrifice layers filled in the lower pillar LMH is removed via the memory holes.

Next, a MANOS structure is formed in the lower pillar LMH and the upper pillar UMH to form the pillars PL (step S131).

Next, slits ST that penetrate the stacked body having the two-tier structure are formed (step S132). The sacrifice layer of the stacked body is removed by pouring a removing liquid such as hot phosphoric acid via the slits ST (step S133). The plurality of word lines WL and the like are formed in the portions from which the sacrifice layers are removed by introducing raw material gas such as tungsten via the slits ST (step S134).

By such a replacement process, the stacked body LM having the two-tier structure in which the plurality of word lines WL and the like are stacked while being separated from each other is formed.

Next, the plate-like portions PT are formed by filling the slits ST with insulating layers or the like (step S135). The separation layers SHE that extend in the memory area MR in the X direction and reach the staircase area SR are formed (step S136). Accordingly, one or a plurality of select gate lines SGD are formed in the upper layer portion of the stacked body LM.

Next, holes for the plugs CH are formed in the upper layer of the stacked body LM (step S141). Here, holes having an elliptic shape when viewed in the stacking direction of the stacked body LM are formed. A plurality of contact holes for the contacts CC are formed in the staircase areas SR (step S142).

Next, the holes and the contact holes are filled with conductive layers such as tungsten layers. As a result, the plugs CH respectively connected to the plurality of pillars PL and the contacts CC respectively connected to the plurality of word lines WL and the select gate lines SGD and SGS are formed (step S143).

Next, the plugs VY and the like connected to each of the plugs CH and the contacts CC are formed in an upper layer above the plugs CH (step S144). Next, the bit lines BL connected to the plugs VY are formed in an upper layer above the plugs VY (step S145). An upper layer wiring connected to the contacts CC via the plugs is formed, for example, in the same layer as the bit lines BL (step S146).

Thereafter, the semiconductor substrate SB on which the peripheral circuit CBA is formed is bonded to the uppermost surface of the supporting substrate on which the stacked body LM, the pillars PL, the plugs CH and VY, the bit lines BL, the contacts CC, the upper layer wiring, and the like are formed (step S151), and the supporting substrate is removed (step S152). The plugs PG and the electrode film EL are sequentially formed on a side from which the supporting substrate is removed (step S153).

Hereinabove, the semiconductor storage device 1 is manufactured.

It should be noted that the process order illustrated in FIG. 5 is merely an example and can be appropriately changed. For example, the process of step S112 and the process of step S113 are interchangeable, and the process of step S122 and the processes of steps S123 and S131 are interchangeable. The process of step S141 and the process of step S142 may also be interchanged.

To achieve high integration of semiconductor storage devices such as three-dimensional nonvolatile memories, the density of pillars in which memory cells are formed is increasing. Therefore, a plurality of pillars arranged in a plurality of columns such as five columns may be arranged in an area between a plate-like portion and a separation layer or an area between separation layers. However, when connecting each of the pillars arranged in the area between the plate-like portion and the separation layer or the area between the separation layers to different bit lines, it becomes difficult to adjust a relative positional relationship between, for example, the pillars, the plugs, and the bit lines.

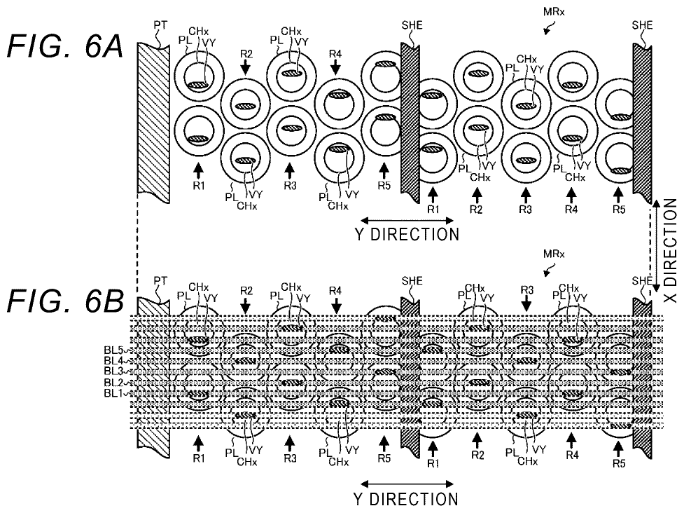

FIGS. 6A and 6B are schematic diagrams illustrating an example of a layout of various components in a memory area MRx of a semiconductor storage device according to a comparative example. More specifically, FIGS. 6A and 6B are partial enlarged views of the memory area MRx, FIG. 6A is a diagram in which the bit lines BL are omitted, and FIG. 6B is a diagram in which the bit lines BL are illustrated.

As illustrated in FIGS. 6A and 6B, the semiconductor storage device according to the comparative example includes plugs CHx having a circular shape when viewed in the stacking direction of the stacked body. Meanwhile, also in the comparative example, the pillars PL are arranged in a staggered arrangement. More specifically, the pillars PL are arranged in five columns extending in the X direction in areas between the plate-like portions PT and the separation layers SHE and areas between the separation layers SHE. Also in the comparative example, the centers of the pillars PL and the plugs CHx substantially coincide with each other, and the positions of the plugs VY in the X direction are respectively different from the positions of the pillars PL and the plugs CHx.

As a result, each of the pillars PL arranged in the areas between the plate-like portions PT and the separation layers SHE or areas between the separation layers SHE can be respectively connected to different bit lines BL. That is, the plurality of bit lines BL are connected to any one of the pillars PL of each of the columns R1 to R5 in a cycle of five columns.

However, in a predetermined column among the columns R1 to R5, it is difficult to sufficiently secure a connection area between the plug VY of which the position in the X direction is determined to match the position of the bit line BL and the plug CHx of which the position in the X direction is determined to match the position of the pillar PL. In the example of FIGS. 6A and 6B, the connection areas between the plugs CHx and VY on the pillar PL that belong to the column R5 and are connected to the bit line BL3 are not sufficient in the areas between the plate-like portion PT and the separation layers SHE and the areas between the separation layers SHE.

More specifically, in a pillar PL that is disposed between the plate-like portion PT and the separation layer SHE and belongs to the column R5, since the plug VY is disposed on the upper side of the page, that is, is extremely close to one side in the X direction with respect to the pillar PL and the plug CHx, the connection area between the plugs CHx and VY is reduced. In a pillar PL that is disposed between the separation layers SHE and belongs to the column R5, since the plug VY is disposed on the lower side of the page, that is, is extremely close to the other side in the X direction with respect to the pillar PL and the plug CHx, the connection area between the plugs CHx and VY is reduced.

When the pillars PL between the plate-like portions PT and the separation layers SHE and between the separation layers SHE are arranged in an odd number of columns, such reduction of the connection area between the plugs CHx and VY may occur when connecting to the bit line BL that is in the middle of the bit lines BL and is connected to the pillar PL in the cycle of the same number as the arrangement of the pillars PL, that is, in the example of FIGS. 6A and 6B, the bit line BL3 that is in the middle of the bit lines BL1 to BL5.

In contrast, the plurality of plugs CH as shown in FIGS. 4A-4D have an elliptic shape in which the longitudinal direction is in the X direction when viewed in the stacking direction of the stacked body LM. Therefore, as illustrated in FIG. 4A and the like, even if the plug VY is disposed extremely close to one side in the X direction with respect to the pillar PL and the plug CH in the pillar PL that belongs to the column R5, the contact area between the plugs CH and VY is sufficiently secured.

The semiconductor storage device 1 includes the plurality of pillars PL arranged in (2n+1) columns (n is an integer of 1 or more) extending in the X direction and the plurality of plugs CH respectively arranged in upper end portions of the plurality of pillars PL and electrically connected to the semiconductor layers CN of the pillars PL, in which a longitudinal direction of the plurality of plugs CHis in a direction intersecting the Y direction. As a result, the highly densely arranged pillars PL can be more reliably connected to the bit lines BL. Therefore, electrical characteristics of the semiconductor storage device 1 are improved, and reliability can be improved.

In the semiconductor storage device 1, the longitudinal direction of the plurality of plugs CH is in the X direction. Therefore, the highly densely arranged pillars PL can be more reliably connected to the bit lines BL.

In the semiconductor storage device 1, the longitudinal direction of the plurality of plugs VY is in the Y direction and the plurality of plugs VY are arranged at positions overlapping the bit lines BL to be connected among the plurality of bit lines BL in the stacking direction of the stacked body LM. Since the longitudinal direction of the plurality of plugs CH is in the X direction as described above, a sufficient contact area can be secured between the plugs CH and the plugs VY arranged to match the positions of the bit lines BL as described above, and thus more reliable connection can be obtained.

In the semiconductor storage device 1, the outer shapes of the plurality of plugs CH when viewed in the stacking direction of the stacked body LM are smaller than the outer shapes of the plurality of pillars PL and the plurality of plugs CH are arranged at positions overlapping the pillars PL to be connected among the plurality of pillars PL in the stacking direction of the stacked body LM. Since the outer shapes of the plurality of plugs CH are smaller than the outer shapes of the plurality of pillars PL as described above, a sufficient contact area between the plugs CH arranged to match the positions of the pillars PL and the plugs VY arranged to match the positions of the bit lines BL is secured as described above, and thus more reliable connection can be obtained.

In the semiconductor storage device 1, the plurality of pillars PL arranged in the (2n+1) columns are arranged in the area between the plate-like portion PT and the separation layer SHE adjacent to each other in the Y direction or the area between the separation layers SHE adjacent to each other in the Y direction. As described above, even if the plurality of pillars PL are arranged in an odd number of columns in the area between the plate-like portion PT and the separation layer SHE or the area between the separation layers SHE, the pillars PL can be more reliably connected to the bit lines BL.

In the semiconductor storage device 1, the pillars PL that belong to the same arrangement among the plurality of pillars PL are connected to bit lines BL having intervals of (2n+1) among the plurality of bit lines BL arranged in the X direction. As such, since the pillars PL that belong to the same arrangement are configured to be connected to the bit lines BL for every bit line BL of the same number as the arrangement of the pillars PL, it is possible to respectively connect the pillars PL arranged in the area between the plate-like portion PT and the separation layer SHE or the area between the separation layers SHE to different bit lines BL.

As described above, pillars PL arranged in five columns extending in the X direction are arranged in the area between the plate-like portion PT and the separation layer SHE and the area between the separation layers SHE. However, the pillars PL may be arranged in three columns or seven columns, as long as the number of columns is an odd number. In the pillars PL arranged in an odd number of columns as described above, by applying the configuration described above, in any of the bit lines BL connected to the pillars PL in the cycle of the same number as the arrangement of the pillars PL, a sufficient connection area between the plugs CH and VY can be secured.

As described above, the source line SL is formed on the supporting substrate before the stacked body LM is formed. However, the source line may be formed after the supporting substrate is bonded to the semiconductor substrate SB and after the supporting substrate is removed.

As described above, the stacked body LM has the two-tier structure. However, the number of tiers of the stacked body may be one or may be three or more.

As described above, the staircase areas SR are arranged in the end portions of the stacked body LM in the X direction. However, the central portion of the stacked body may be dug down in a staircase shape so that the staircase area is disposed in the central portion of the stacked body when viewed in the stacking direction.

### Modification Example

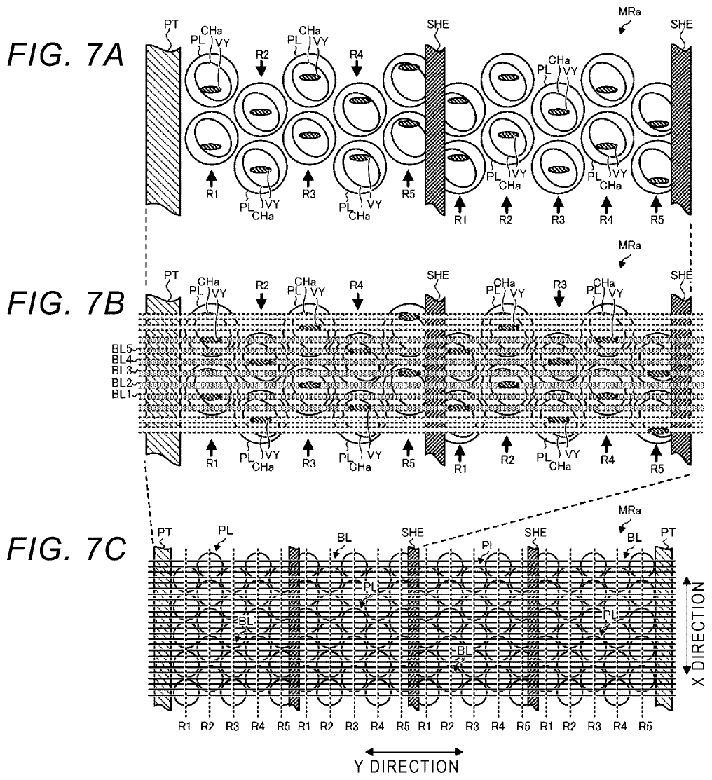

Next, a semiconductor storage device 1 according to a modification example is described with reference to FIGS. 7A to 7C. In the semiconductor storage device 1 of the modification example, the direction of the longitudinal direction of a plug CHa is different from the direction of the plug CH described above.

It should be noted that, in the accompanying drawing, the same component described above is denoted by the same reference numerals, and the description thereof may be omitted.

FIGS. 7A to 7C are schematic diagrams illustrating an example of a layout of various components in a memory area MRa of the semiconductor storage device 1 according to the modification example.

More specifically, FIGS. 7A and 7B are partial enlarged views of the memory area MRa, FIG. 7A is a diagram in which the bit lines BL are omitted, and FIG. 7B is a diagram in which the bit lines BL are illustrated. FIG. 7C is a schematic top view illustrating a part of the memory area MRa.

As illustrated in FIG. 7C, the layout of the pillars PL, the plurality of bit lines BL above the pillars PL, and the like in the memory area MRa of the modification example is the same as the one described above. That is, in the area between the plate-like portion PT and the separation layer SHE and the area between the separation layers SHE, the plurality of pillars PL are arranged in an odd number of columns such as five columns extending in the X direction and are arranged in a staggered arrangement as a whole. Above the pillars PL, the plurality of bit lines BL separated from each other in the X direction and respectively extending in the Y direction are arranged.

As illustrated in FIGS. 7A and 7B, in the semiconductor storage device 1 of the modification example, the plurality of plugs CHa have an elliptic shape or the like in which the longitudinal direction thereof is in a direction intersecting both the X direction and the Y direction. An angle formed between the direction of the longitudinal direction of the plurality of plugs CHa and the plurality of bit lines BL extending in the Y direction is preferably 30° or more and 60° or less.

It should be noted that the shape of the plurality of plugs CHa is not limited to the elliptic shape and may be other shapes such as an oval shape or a rectangular shape with rounded corners.

As such, also in the semiconductor storage device 1 of the modification example in which the longitudinal direction is oblique to both the X direction and the Y direction, the plurality of plugs CHa can connect the respective pillars PL arranged between the plate-like portion PT and the separation layer SHE adjacent to each other in the Y direction and between the separation layers SHE adjacent to each other in the Y direction to different bit lines BL. Here, the plurality of bit lines BL are connected to any one of the pillars PL of each of the columns R1 to R5 in a cycle of five columns.

In the semiconductor storage device 1 according to the modification example, the angle formed between the longitudinal direction of the plurality of plugs CHa and the plurality of bit lines BL is 30° or more and 60° or less. As a result, a distance between the plugs CHa adjacent to each other in the X direction can be set to be longer, and thus exposure, etching processing, and the like for forming patterns of the plurality of plugs CHa become easier. A distance between the plugs CHa adjacent to each other in the X direction becomes longer, and thus it is possible to prevent delays in transmission speeds of various signals transmitted via the plugs CHa.

The semiconductor storage device 1 of the modification example exhibits the same effect as in the semiconductor storage device 1 described above as well.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a plurality of conductive layers arranged in a first direction and separated from each other;
a plurality of pillars extending along the first direction and arranged in (2n+1) columns (n is an integer of 1 or more) along a second direction intersecting the first direction, each of the pillars including a semiconductor layer;
a plurality of first plugs, each of which is on an upper end portion of a corresponding one of the pillars and electrically connected to the semiconductor layer; and
a plurality of bit lines extending along the second direction above the pillars, each of the bit lines being electrically connected to two or more of the first plugs, wherein
each of the first plugs has an elongated shape at a cross-section taken thereof in a plane perpendicular to the first direction and a longitudinal direction of the cross-section forms an angle with respect to the second direction when viewed from the first direction.

2. The semiconductor storage device according to claim 1, wherein
the angle is 30° or more and 60° or less.

3. The semiconductor storage device according to claim 1, wherein
the first plugs have an elliptic shape when viewed from the first direction.

4. The semiconductor storage device according to claim 1, further comprising:
a plurality of second plugs, each of which is on a corresponding one of the first plugs.

5. The semiconductor storage device according to claim 4, wherein
one of the bit lines is electrically connected to two or more of the first plugs via the second plugs thereon.

6. The semiconductor storage device according to claim 4, wherein
a longitudinal direction of each of the second plugs is the second direction or is parallel to the second direction.

7. The semiconductor storage device according to claim 6, wherein
the longitudinal direction of each of the second plugs intersects the longitudinal direction of each of the first plugs.

8. The semiconductor storage device according to claim 4, wherein
each of the second plugs overlaps any one of the bit lines when viewed from the first direction.

9. The semiconductor storage device according to claim 4, wherein
the second plugs have an elliptic shape when viewed from the first direction.

10. The semiconductor storage device according to claim 1, wherein
an area of an outer shape of the first plugs is smaller than an area of an outer shape of the pillars when viewed from the first direction.

11. The semiconductor storage device according to claim 10, wherein
each of the first plugs is within the outer shape of the corresponding pillar when viewed from the first direction.

12. The semiconductor storage device according to claim 1, further comprising:
first and second plate-like portions extending parallel to the pillars, wherein
the pillars are between the first and second plate-like portions.

13. The semiconductor storage device according to claim 12, further comprising:
a plurality of separation layers extending parallel to the first and second plate-like portions therebetween and penetrating at least an uppermost conductive layer of the conductive layers, wherein
each of the pillars is between the first plate-like portion and one of the separation layers adjacent thereto or between two of the separation layers that are adjacent to each other.

14. The semiconductor storage device according to claim 13, wherein
one of the pillars adjacent to one of the separation layers partially overlaps said one of the separation layers when viewed from the first direction.

15. The semiconductor storage device according to claim 13, wherein
five columns of pillars are between the first plate-like portion and one of the separation layers adjacent thereto and between two of the separation layers that are adjacent to each other.

16. The semiconductor storage device according to claim 13, wherein
the bit lines are arranged along a third direction intersecting the first and second directions, the bit lines being separated from each other, and
pillars of a same column are connected to bit lines at intervals of (2n+1).

17. The semiconductor storage device according to claim 16, wherein
(2n+1) adjacent bit lines are respectively connected to pillars in different columns.

18. The semiconductor storage device according to claim 16, wherein
center points of pillars in a first column are offset from center points of pillars in a second column adjacent to the first column in both the second direction and a third direction intersecting the first and second directions when viewed from the first direction.

19. The semiconductor storage device according to claim 1, wherein the pillars are arranged in a staggered pattern when viewed from the first direction.

20. A semiconductor storage device comprising:
a plurality of conductive layers arranged in a first direction and separated from each other;
a plurality of pillars extending along the first direction and arranged along a second direction intersecting the first direction, each of the pillars including a semiconductor layer;
a plurality of first plugs, each of which is on an upper end portion of a corresponding one of the pillars and electrically connected to the semiconductor layer;
a plurality of second plugs, each of which is on a corresponding one of the first plugs;
a plurality of bit lines extending along the second direction above the pillars, each of the bit lines being electrically connected to two or more of the second plugs;
first and second plate-like portions extending parallel to the pillars; and
a plurality of separation layers extending parallel to the first and second plate-like portions therebetween and penetrating at least an uppermost conductive layer of the conductive layers, wherein
five columns of pillars are between the first plate-like portion and one of the separation layers adjacent thereto and between two of the separation layers that are adjacent to each other, and
each of the first plugs has an elongated shape at a cross-section taken thereof in a plane perpendicular to the first direction and a longitudinal direction of the cross-section forms an angle with respect to the second direction when viewed from the first direction.
